(19) United States
(12) Patent Application Publication
(10) Pub. No.: US 2023/0034431 A1
(43) Pub. Date: Feb. 2, 2023

(54) COVERS FOR ELECTRONIC DEVICES WITH A HYDROPHOBIC COATING

(71) Applicant: Hewlett-Packard Development Company, L.P., Spring, TX (US)

(72) Inventors: Kuan-Ting Wu, Taipei City (TW); Ya-Ting Yeh, Taipei City (TW); Chi Hao Chang, Taipei City (TW)

(73) Assignee: Hewlett-Packard Development Company, L.P., Spring, TX (US)

(21) Appl. No.: 17/786,619

(22) PCT Filed: Jan. 8, 2020
(86) PCT No.: PCT/US2020/012757

§ 371 Date: Jun. 17, 2022

(51) Int. Cl. H05K 5/06; H05K 5/03

(52) U.S. Cl. CPC H05K 5/065; H05K 5/03

(57) ABSTRACT

This application describes covers for electronic devices, electronic devices, and methods for making the covers. In one example, a cover comprises a substrate comprising a first metal; a second metal injection molded 10 on the surface of the substrate; a paint layer or an electrophoretic deposition layer on the second metal surface; a chamfered edge on the substrate, wherein the chamfered edge cuts through the paint layer or the electrophoretic deposition layer, the second metal, and partially through the first metal; and a hydrophobic coating.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market. Devices such as mobile phones, tablets and portable computers are generally provided with a casing. The casing typically provides a number of functional features, e.g. protecting the device from damage.

### BRIEF DESCRIPTION OF THE DRAWING

FIGS. 1A-1D are a cross-sectional view illustrating an example cover for an electronic device in accordance with examples of the present disclosure;

FIG. 2 is a perspective view illustrating an example cover for an electronic device in accordance with examples of the present disclosure; and

FIG. 3 is a flowchart illustrating an example method of making a cover for an electronic device in accordance with examples of the present disclosure.

### DETAILED DESCRIPTION

In some examples, described herein is a cover for an electronic device comprising: a substrate comprising a first metal; a second metal injection molded on the surface of the substrate; a paint layer or an electrophoretic deposition layer on the second metal surface; a chamfered edge on the substrate, wherein the chamfered edge cuts through the paint layer or the electrophoretic deposition layer, the second metal, and partially through the first metal; and a hydrophobic coating.

In some examples, the first metal comprises aluminum and aluminum alloys, titanium and titanium alloys, stainless steel, and combinations thereof.

In some examples, the second metal comprises magnesium and magnesium alloys, aluminum and aluminum alloys, and combinations thereof.

In some examples, the chamfered edge is formed using a computer numerical control (CNC) mill or laser engraving.

In some examples, the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof.

In some examples, the hydrophobic coating has a thickness of from about 10 nm to about 100 nm.

In some examples, the paint layer comprises: a primer layer; a base coat layer; and a top coat layer.

In some examples, the primer layer comprises polyurethane, epoxy, epoxy-polyester, polyester, and combinations thereof.

In some examples, the base coat layer comprises: polyurethane, polyacrylic, polyester, and combinations thereof; and pigments, wherein the pigments are selected from the group consisting of carbon black, titanium dioxide, clay, mica, talc, barium sulfate, calcium carbonate, aluminum oxide, plastic heads, color pigments, dyes, and combinations thereof.

In some examples, the top coat layer comprises polyacrylics, polyurethanes, urethane acrylates, acrylic acrylates, epoxy acrylates, and combinations thereof.

In some examples, disclosed herein is an electronic device comprising: an electronic component; and a cover enclosing the electronic component, the cover comprising: a substrate comprising a first metal; a second metal injection molded on the surface of the substrate; a paint layer or an electrophoretic deposition layer on the second metal surface: a chamfered edge on the substrate, wherein the chamfered edge cuts through the paint layer or the electrophoretic deposition layer, the second metal, and partially through the first metal; and a hydrophobic coating.

In some examples, the electronic device is a laptop, a desktop computer, a keyboard, a mouse, a smartphone, a tablet, a monitor, a television screen, a speaker, a game console, a video player, an audio player, or a combination thereof.

In some examples, the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof; and the hydrophobic coating has a thickness of from about 10 nm to about 100 nm.

In some examples, disclosed herein is a method of making a cover for an electronic device comprising: depositing a first metal on a substrate; injection molding a second metal on the surface of the substrate; applying a paint layer or an electrophoretic deposition layer on the second metal surface; chamfering an edge on the substrate, wherein the chamfered edge cuts through the paint layer or the electrophoretic deposition layer, the second metal, and partially through the first metal: and then applying a hydrophobic coating.

In some examples, the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof; and the hydrophobic coating has a thickness of from about 10 nm to about 100 nm.

It is noted that when discussing the cover, the electronic device, or the method of manufacturing the cover, such discussions of one example are to be considered applicable to the other examples, whether or not they are explicitly discussed in the context of that example. Thus, in discussing a metal alloy in the context of the cover, such disclosure is also relevant to and directly supported in the context of the electronic device, the method of manufacturing the multi-color electronic housing, and vice versa.

### Covers for Electronic Devices

The present disclosure describes covers for electronic devices that can be strong and lightweight and have a decorative appearance. The cover can provide an enclosure for an electronic device and the enclosure can include a substrate.

In some examples, the first metal comprises aluminum and aluminum alloys, titanium and titanium alloys, stainless steel, and combinations thereof. In some examples, the second metal comprises magnesium and magnesium alloys, aluminum and aluminum alloys, and combinations thereof.

The first metal and the second metal can be the same or different. These metals used for the substrate may be a light metal. The term “light metal” refers to metals and alloys that are generally any metal of relatively low density including metal that is less than about 5 g/cm³ in density. In some cases, light metal can be a material including aluminum, magnesium, titanium, lithium, zinc, and alloys thereof. These light metals can have useful properties, such as low weight, high strength, and an appealing appearance.

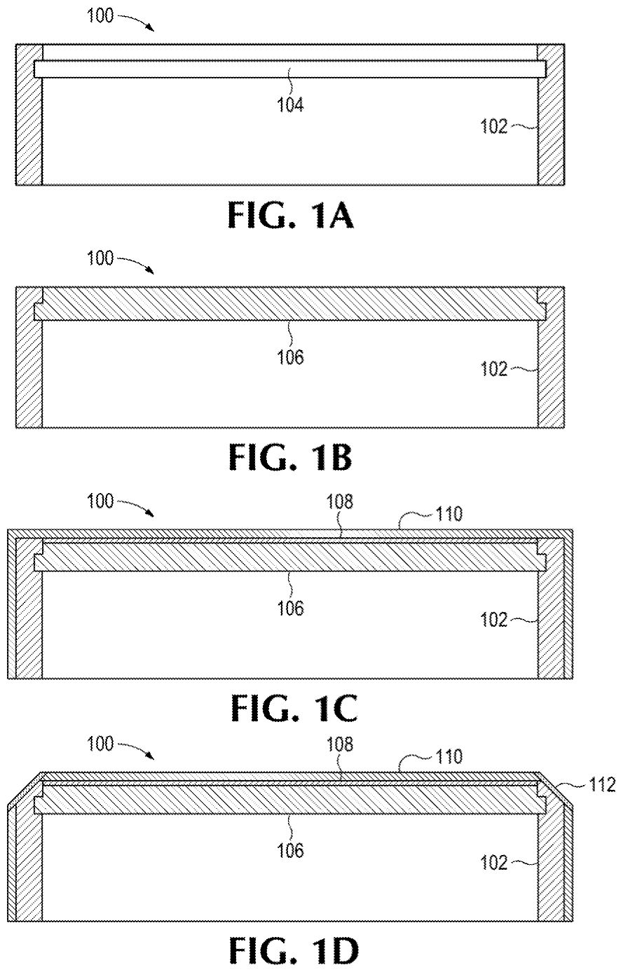

FIG. 1A shows an example cover 100 for an electronic device. The cover 100 includes a substrate 102. The substrate can comprise a first metal in the shape of a frame 104.

FIG. 1B shows the example cover 100 for the electronic device from FIG. 1A. The cover 100 includes the substrate 102. The substrate can compose a second metal 106 injection molded to fully or partially enclose the first metal frame 104.

FIG. 1C shows a paint layer or an electrophoretic deposition layer 108. Then a hydrophobic coating 110.

FIG. 1D shows a chamfered edge with a high gloss surface finish 112. While not shown, the surface of high gloss surface finish 112 is also coated with a hydrophobic coating.

As shown in FIG. 1D, in this example an edge of the cover 100 is chamfered by cutting away material along a 90° angled edge of the thermoplastic insert molding at about a 45° angle so that the 90° edge is replaced by a sloped surface at about 45°. Accordingly, as used herein, “chamfer” refers to the action of cutting away an edge where two faces meet to form a sloping face transitioning between the two original faces. In some cases, the term “chamfered edge” can refer to the entire transition area between the original faces and the metal at the edge before chamfering together with the sloped face created by the chamfering. In other cases, the term “chamfered edge” may refer specifically to the sloped face created by the chamfering. In many cases, the original edge can be a 90° angle edge, and the chamfer can create a sloping face at about a 45° angle. However, in some examples the original edge can have a different angle and the chamfer can create a sloping surface with a different angle. The chamfer can be performed using CNC techniques, laser engraving, or laser trimming. In further examples, chamfering can be performed using a milling machine with a cutting bit oriented to cut away the edge and create the sloped surface of the chamfered edge. In other examples, the chamfer can be performed by laser cutting, water jet cutting, sanding, or any other suitable method.

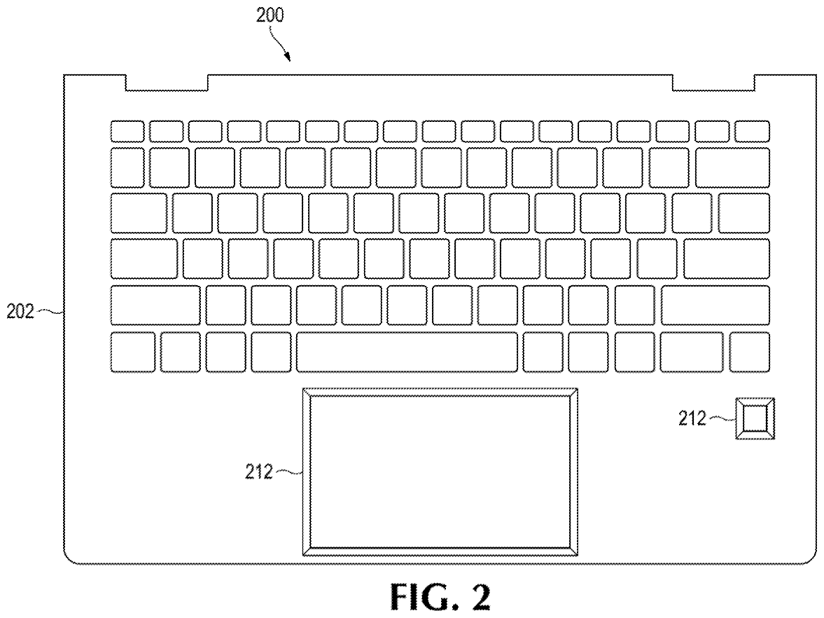

FIG. 2 shows an example cover 200 for an electronic device. The cover 200 includes a substrate 202 with a glossy first metal chamfer 212 in the track pad and fingerprint scanner areas. This example is a top cover for the keyboard portion of a laptop (sometimes referred to as a “laptop cover C”). The cover includes key openings for the keyboard buttons to be positioned therethrough, hinge recesses to receive a hinge, a track pad opening to receive a track pad, and a fingerprint scanner opening to receive a fingerprint scanner. These are merely examples of structures that may be present, and are illustrative of many of a number of other structural components used with this type of top cover.

Depending on the shape and design of a cover for an electronic device, the cover may have many different edges. Any of these edges can be chamfered depending on the desired final appearance of the cover. More particularly, in some examples the substrate (including either the entire substrate, a portion of the substrate, or multiples portions of the substrate) can be coated with the hydrophobic coating.

As used herein, “cover” refers to the exterior shell of an electronic device that includes or is in the form of an enclosure, and a portion thereof (or the structure thereof) includes a substrate. In other words, the cover can be adapted to contain the internal electronic components of the electronic device. The cover can be an integral part of the electronic device. The term “cover” is not meant to refer to the type of removable protective cases that are often purchased separately for an electronic device (especially smartphones and tablets) and placed around the exterior of the electronic device. Covers as described herein can be used on a variety of electronic devices. For example, a laptop, a desktop, a keyboard, a mouse, a printer, a smartphone, a tablet, a monitor, a television, a speaker, a game console, a video player, an audio player, or a combination thereof. In various examples, the light metal substrate for these covers can be formed by molding, casting, machining, bending, working, stamping, or another process. In one example, a light metal substrate can be milled from a single block of metal. In other examples, the cover can be made from multiple panels. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). Covers can also be made for smartphones and tablet computers with a single metal piece or multiple metal panels.

As used herein, a layer that is referred to as being “on” a lower layer can be directly applied to the lower layer, or an intervening layer or multiple intervening layers can be located between the layer and the lower layer. Generally, the covers described herein can include a substrate and a thermoplastic insert molding both covered with a paint coating. Accordingly, a layer that is “on” a lower layer can be located further from the substrate. However, in some examples there may be other intervening layers such as a primer layer underneath the protective layer. Thus, a “higher” layer applied “on” a “lower” layer may be located farther from the substrate and closer to a viewer viewing the cover from the outside.

It is noted that when discussing covers for electronic devices, the electronic devices themselves, or methods of making covers for electronic devices, such discussions can be considered applicable to one another whether or not they are explicitly discussed in the context of that example. Thus, for example, when discussing the metals used in the light metal substrate in the context of one of the example covers, such disclosure is also relevant to and directly supported in the context of the electronic devices and/or methods, and vice versa. It is also understood that terms used herein will take on their ordinary meaning in the relevant technical field unless specified otherwise. In some instances, there are terms defined more specifically throughout or included at the end of the present disclosure, and thus, these terms are supplemented as having a meaning described herein.

### Electronic Devices

A variety of electronic devices can be made with the covers described herein. In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, track pads, fingerprint scanners, cameras, and so on. Accordingly, the covers described herein can include openings for these components. Other electronic components may be designed to be completely enclosed, such as motherboards, batteries, sim cards, wireless transceivers, memory storage drives, and so on. Additionally, in some examples a cover can be made up of two or more cover sections, and the cover sections can be assembled together with the electronic components to enclose the electronic components. As used herein, the term “cover” can refer to an individual cover section or panel, or collectively to the cover sections or panels that can be assembled together with electronic components to make the complete electronic device.

In further examples, the electronic device can be a laptop, a desktop, a keyboard, a mouse, a printer, a smartphone, a tablet, a monitor, a television, a speaker, a game console, a video player, an audio player, or a variety of other types of electronic devices. In certain examples, the chamfered edge or edges can be located in decorative locations on the cover. Some examples include chamfered edges around track pads, around fingerprint scanners, around an edge of a logo, and so on. In further detail, there may be outer periphery of the substrate or thermoplastic insert molding that can be similarly chamfered.

### Methods of Making Covers for Electronic Devices

In some examples, the covers described herein can be made by first forming the substrate. This can be accomplished using a variety of processes, including molding, insert molding, forging, casting, machining, stamping, bending, working, and so on. The substrate can be made from a variety of metals or other materials. In one example, sheet or forge metal is insert molded into the shape of a cover. In certain examples, the substrate can include two different types of metals. The metal for the substrate may be aluminum, magnesium, lithium, titanium, and alloys thereof. As mentioned above, in some examples the substrate can be a single piece while in other examples the substrate can include multiple pieces that each make up a portion of the cover. Additionally, in some examples the substrate can be a composite made up of multiple metals combined, such as having layers of multiple different metals, other materials, or panels or other portions of the substrate being different metals or other materials.

A paint layer and/or an electrophoretic deposition layer can be applied to a surface of the injection molded second metal. In some examples, the paint layer and/or the electrophoretic deposition layer can be applied to any surface of the substrate including the first and/or second metals, including fully or partially covering a single surface, fully or partially covering multiple surfaces, or fully or partially covering the light metal substrate as a whole. The paint layer and/or the electrophoretic deposition layer can be applied by any suitable application method.

The chamfered edges can be formed by cutting through the paint layer or the electrophoretic deposition layer, the second metal, and partially through the first metal. In various examples, chamfered edges can be formed at any edge or combination of edges on the cover. The chamfered edge can vary in depth. The term “depth” of chamfered edges refers to the amount of the edge that is cut away by the chamfering process. The depth of the chamfer can be stated in terms of the distance from the original edge of the cover to the edge of the sloped surface created by the chamfering. In various examples, the chamfer can be from about 0.1 mm to about 1 cm deep. In other examples, the chamfer can be from about 0.2 mm to about 5 mm deep. As stated above, in some examples the chamfer can be symmetrical so that the same amount of material is removed on both faces of the cover that meet at the chamfered edge. In a symmetrical chamfering of a 90° edge, the new sloped surface created by the chamfering is at a 45° angle with respect to the original faces of the cover. However, in other examples, the chamfer can be asymmetrical so that the angle of the sloped surface is different with respect to each of the original faces of the cover. The examples of the depth of the chamfer described above can refer to either side of the chamfer in the case of an asymmetrical chamfer.

The chamfered edge can be formed using any suitable process that can remove material at the edge of the cover and produce a sloped surface in place of the original edge. In some examples, the chamfer can be formed using a CNC machine such as a milling machine, a router, a laser engraver, a laser cutter, a water jet cutter, a sander, a file, or other methods.

A second metal layer of the present technology can be covered with an electrophoretic deposition layer. The electrophoretic deposition layer can be deposited and can include a polymeric binder, a pigment, and a dispersant. The electrophoretic deposition layer can include transparent, semi-transparent, and opaque finishes of any desired color as described in more detail below. In certain examples, multiple different colors can be deposited over multiple different chamfered edges of the cover.

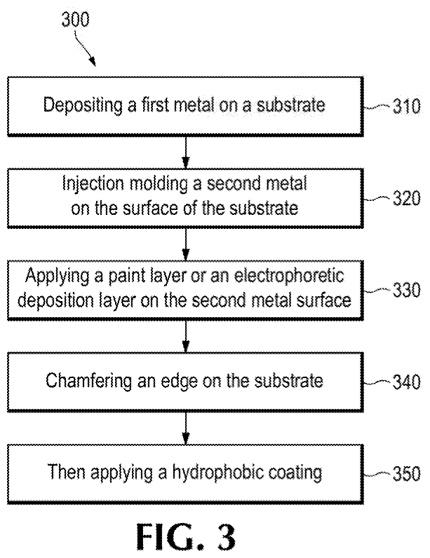

FIG. 3 is a flowchart illustrating an example method 300 of making a cover for an electronic device. The method includes depositing a first metal on a substrate 310; injection molding a second metal on the surface of the substrate 320; applying a paint layer or an electrophoretic deposition layer on the second metal surface 330; chamfering an edge on the substrate 340, wherein the chamfered edge cuts through the paint layer or the electrophoretic deposition layer, the second metal, and partially through the first metal; and then applying a hydrophobic coating 350.

### Substrates for Electronic Device Covers

In some examples, a cover for an electronic; device can comprise: a substrate comprising a first metal and a second metal injection molded on the surface of the substrate.

In some examples, the first metal comprises aluminum and aluminum alloys, titanium and titanium alloys, stainless steel, and combinations thereof. In some examples, the second metal comprises magnesium and magnesium alloys, aluminum and aluminum alloys, and combinations thereof.

The substrate can be made from a first metal and a second metal which can be the same or different. The first metal and the second metal for the substrate may be aluminum, magnesium, lithium, titanium, or alloys thereof. Non-limiting examples of elements that can be included in aluminum or magnesium alloys can include aluminum, magnesium, titanium, lithium, niobium. zinc, bismuth, copper, cadmium, iron, thorium, strontium, zirconium, manganese, nickel, lead, silver, chromium, silicon, tin, gadolinium, yttrium, calcium, antimony, cerium, lanthanum, or others.

In some examples, the substrate can include an aluminum magnesium alloy combination such that the aluminum is present in the substrate in an amount of from about 87% to 99.5% and the magnesium is present in the substrate in an amount of from about 0.5% to about 13% by weight based on the total weight of the substrate. Examples of specific aluminum magnesium alloys can include 1050, 1060, 1199, 2014, 2024. 2219, 3004, 4041, 5005, 5010, 5019, 5024, 5026, 5050, 5052, 6056, 5059, 5083, 5086, 5154, 5182, 5252, 5254, 5356, 5454, 5456, 5457, 5557, 5652, 5657, 5754, 6005, 6005A, 6060, 6061, 6063, 6066, 6070, 6082, 6105, 6162, 6262, 6351, 6463, 7005, 7022, 7068, 7072, 7075, 7079, 7116, 7129, and 7178.

In further examples, the substrate can include magnesium metal, a magnesium alloy that can be about 99 wt % or more magnesium by weight, or a magnesium alloy that is from about 50 wt % to about 99 wt % magnesium by weight. In a particular example, the substrate can include an alloy including magnesium and aluminum. Examples of magnesium-aluminum alloys can include alloys made up of from about 91% to about 99% magnesium by weight and from about 1% to about 9% aluminum by weight, and alloys made up of about 0.5% to about 13% magnesium by weight and 87% to 99.5% aluminum by weight. Specific examples of magnesium-aluminum alloys can include AZ63, AZ81, AZ91, AM50, AM60, AZ31, AZ61, AZ80, AE44, AJ82A, ALZ391, AMCa602, LZ91, and Magnox.

The substrate can be shaped to fit any type of electronic device, including the specific types of electronic devices described herein. In some examples, the substrate can have any thickness suitable for a particular type of electronic device. The thickness of the metal in the substrate can be selected to provide a desired level of strength and weight for the cover of the electronic device. In some examples, the substrate can have a thickness from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

### Paint Layer for Electronic Device Covers

In some examples, a paint layer is applied over the second metal surface. The paint layer may include one, two, three or four layers or any other number of layers. The paint layer may include a primer coat, a base coat, and/or a top coat. The paint layer may be applied using any number of techniques including spray painting or inkjet painting. The paint layer may be composed of a variety of materials. In one example, a primer coat can include a polyester, a polyurethane, or a copolymer thereof. In one example, a base coat can include a polyester, a polyurethane, or a copolymer thereof. In one example, a top coat can include a polyurethane, a polyacrylic or polyacrylate, a urethane, an epoxy, or a copolymer thereof. The paint layer can be any number of colors and can be transparent, semi-transparent, or opaque.

In some examples, the paint layer can comprise a colorant and a polymeric binder. In some examples, the paint layer can be an electrophoretic deposition coating comprising a polymer binder, a pigment, and a dispersant.

In some examples, a paint layer can be applied over the second metal. In a certain example, the paint layer can include a polymer resin. In certain examples, the polymer resin can be transparent and the paint layer can be a clear coat layer that allows the color of the underlying materials to show through. In further examples, the paint layer may be colored. In a particular example, the paint layer can include a layer of colored coating and a layer of dear coating on the colored coating. In some examples, the polymer resin of the dear coat layer can be dear poly(meth)acrylic, dear polyurethane, clear urethane (meth)acrylate, clear (meth)acrylic (meth)acrylate, or clear epoxy (meth)acrylate coating.

In further examples, the paint layer can include fillers such as pigment dispersed in an organic polymer resin. Non-limiting examples of pigments used in the protective coating layer can include carbon black, titanium dioxide, clay, mica, talc, barium sulfate, calcium carbonate, synthetic pigment, metallic powder, aluminum oxide, graphene, pearl pigment, or a combination thereof. The pigment can be present in the paint layer in an amount from about 0.5 wt % to about 30 wt % with respect to dry components of the paint layer, in some examples. In other examples, the amount of pigment can be from about 1 wt % to about 25 wt % or from about 2 wt % to about 15 wt % with respect to dry components of the paint layer.

The polymer resin included in the paint layer with the pigment can include polyester, poly(meth)acrylic, polyurethane, epoxy, urethane (meth)acrylic, (meth)acrylic (meth)acrylate, epoxy (meth)acrylate, or a combination thereof. As used herein, a “combination” of multiple different polymers can refer to a blend of homopolymers, a copolymer made up of the different polymers or monomers thereof, or adjacent layers of the different polymers. In certain examples, the polymer resin of the protective coating layer can have a weight-average molecular weight from about 100 g/mol to about 6,000 g/mol.

The thickness of the paint layer can be from about 5 μm to about 100 μm in some examples. In further examples, the thickness can be from about 10 μm to about 25 μm, or less than about 100 μm, or less than about 90 μm, or less than about 80 μm, or less than about 70 μm, or less than about 60 μm, or less than about 50 μm, or less than about 40 μm, or less than about 30 μm, or less than about 20 μm, or less than about 15 μm, or less than about 10 μm.

In certain examples, the paint layer can include a base coat that is colored and a top coat that is clear. Thus, the colored layer and the clear coat layer described above can be used together in certain examples. The overall thickness of the base coat with the top coat can be from about 2 μm to about 100 μm, or from about 5 μm to about 60 μm, or from about 10 μm to about 40 μm, in some examples.

In further examples, the colored paint layer, the top clear coat layer, or both, can be radiation curable. The polymer resin used in these layers can be curable using heat and/or radiation. For example, a heat curing polymer resin can be used and then cured in an oven for a sufficient curing time. A radiation curing polymer resin can be exposed to sufficient radiation energy to cure the polymer resin. The paint layer can be cured after applying the layer to the cover. In certain examples, curing can include heating the paint layer at a temperature from about 50° C. to about 80° C., or from about 50° C. to about 60° C., or from about 60° C. to about 80° C. The layer can be heated for a curing time from about 5 minutes to about 40 minutes, or from about 5 minutes to about 10 minutes, or from about 20 minutes to about 40 minutes. In other examples, curing can include exposing the layer to radiation energy at an intensity from about 500 mJ/cm² to about 2,000 mJ/cm² or from about 700 mJ/cm² to about 1,300 mJ/cm². The layer can be exposed to the radiation energy for a curing time from about 5 seconds to about 30 seconds, or from about 10 seconds to about 30 seconds.

### Electrophoretic Deposition Layers for Electronic Device Covers

In some examples, the second metal surface can be covered with an electrophoretic deposition layer. The electrophoretic deposition layer or coating can include a polymeric binder, a pigment, and a dispersant. The electrophoretic coating process can sometimes be referred to as “electropainting” or “electrocoating” because of the use of electric current in the process. To deposit an electrophoretic coating on the cover of the electronic device, the metal substrate can be placed in a coating bath. The coating bath can include a suspension of particles including the polymeric binder, pigment, and dispersant. In certain examples, the solid content of the coating bath can be from about 3 wt % to about 30 wt % or from about 5 wt % to about 15 wt %. The metal substrate can be electrically connected to an electric power source. The metal substrate can act as one electrode and the power source can also be attached to a second electrode that is also in contact with the coating bath. An electric current can be run between the metal substrate and the second electrode. In certain examples, the electric current can be applied at a voltage from about 30 V to about 150 V. The electric current can cause the particles suspended in the coating bath to migrate to the surface of the second metal substrate and coat the surface. After this deposition process, additional processing may be performed such as rinsing the metal substrate, baking the coated substrate to harden the coating, or exposing the coated substrate to radiation to cure radiation curable polymeric binders.

In some examples, electrophoretic coatings can include the same pigments and polymeric binders or resins described above in the paint-type protective coating. The thickness of the coating can also be in the same ranges described above. Different colors can be applied to different chamfered edges of the metal substrate.

In certain examples, the electrophoretic deposition layer can have a thickness from about 1 μm to about 50 μm, from about 2 μm to about 30 μm, or from about 15 μm to about 25 μm. In other examples, the clear coating layer can be a polyurethane with a thickness from about 10 μm to about 100 μm, from about 30 μm to about 75 μm, or from about 40 μm to about 50 μm.

### Hydrophobic Coating

In some examples, the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof.

The hydrophobic coating can have a thickness of from about 10 nm to about 100 nm, or from about 15 nm to about 95 nm, or from about 20 nm to about 90 nm, or from about 25 nm to about 65 nm, or from about 30 nm to about 80 nm, or from about 35 nm to about 75 nm, or from about 40 nm to about 70 nm.

In some examples, the hydrophobic coating can comprise C7 or higher hydrophobic fluoropolymers, C6 or lower fluorotelomers, UV fluoropolymers, or combinations thereof.

In some examples, the hydrophobic coating comprises a fluoropolymer selected from the group consisting of fluoroacrylates, fluorosilicone acrylates, fluorourethanes, perfluoropolyethers, perfluoropolyoxetanes, polytetrafluoroethylene (PTFE), polyvinylidenefluourides (PVDF), fluorosiloxanes, or combinations thereof.

In some examples, the hydrophobic coating can be cured by heating to a temperature of from about 70° C. to about 180° C. for from about 30 minutes to about 180 minutes.

In some examples, radiation energy can be applied to the hydrophobic coating to cure the fluoropolymers. In certain examples, the hydrophobic coating can be cured by applying UV radiation. Curing can include exposing the coating to radiation energy at an intensity from about 500 mJ/cm² to about 2,000 mJ/cm² or from about 700 mJ/cm² to about 1,300 mJ/cm². The layer can be exposed to the radiation energy for a curing time from about 5 seconds to about 30 seconds, or from about 10 seconds to about 30 seconds. In other examples, curing can include heating at a temperature from about 50° C. to about 80° C. or from about 50° C. to about 60° C. or from about 60° C. to about 80° C. The hydrophobic coating can be heated for a curing time from about 5 minutes to about 40 minutes, or from about 5 minutes to about 10 minutes, or from about 20 minutes to about 40 minutes, in some examples.

### Definitions

It is noted that, as used in this specification and the appended claims, the singular forms “a,” “an,” and “the” include plural referents unless the content clearly dictates otherwise.

The term “about” as used herein, when referring to a numerical value or range, allows for a degree of variability in the value or range, for example, within 5% or other reasonable added range breadth of a stated value or of a stated limit of a range. The term “about” when modifying a numerical range is also understood to include the exact numerical value indicated, e.g., the range of about 1 wt % to about 5 wt % includes 1 wt % to 5 wt % as an explicitly supported sub-range.

As used herein, “colorant” can include dyes and/or pigments.

As used herein, “dye” refers to compounds or molecules that absorb electromagnetic radiation or certain wavelengths thereof. Dyes can impart a visible color to an ink if the dyes absorb wavelengths in the visible spectrum.

As used herein, “pigment” generally includes pigment colorants, magnetic particles, aluminas, silicas, and/or other ceramics, organo-metallics or other opaque particles, whether or not such particulates impart color. Thus, though the present description primarily exemplifies the use of pigment colorants, the term “pigment” can be used more generally to describe pigment colorants and other pigments such as organometallics, ferrites, ceramics, etc. In one specific example, however, the pigment is a pigment colorant.

As used herein, a plurality of items, structural elements, compositional elements, and/or materials may be presented in a common list for convenience. However, these lists should be construed as though the individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also to include all the individual numerical values or sub-ranges encompassed within that range as if individual numerical values and sub-ranges are explicitly recited. For example, a layer thickness from about 0.1 μm to about 0.5 μm should be interpreted to include the explicitly recited limits of 0.1 μm to 0.5 μm, and to include thicknesses such as about 0.1 μm and about 0.5 μm, as well as subranges such as about 0. μm to about 0.4 μm, about 0.2 μm to about 0.5 μm, about 0.1 μm to about 0.4 μm etc.

The following illustrates an example of the present disclosure. However, it is to be understood that the following is illustrative of the application of the principles of the present disclosure. Numerous modifications and alternative compositions, methods, and systems may be devised without departing from the spirit and scope of the present disclosure. The appended claims are intended to cover such modifications and arrangements.

What is claimed is:

1. A cover for an electronic device comprising:
a substrate comprising a first metal;
a second metal injection molded on the surface of the substrate;
a paint layer or an electrophoretic deposition layer on the second metal surface;
a chamfered edge on the substrate, wherein the chamfered edge cuts through the paint layer or the electrophoretic deposition layer, the second metal, and partially through the first metal; and
a hydrophobic coating.

2. The cover of claim 1, wherein the first metal comprises aluminum and aluminum alloys, titanium and titanium alloys, stainless steel, and combinations thereof.

3. The cover of claim 1, wherein the second metal comprises magnesium and magnesium alloys, aluminum and aluminum alloys, and combinations thereof.

4. The cover of claim 1, wherein the chamfered edge is formed using a computer numerical control (CNC) mill or laser engraving.

5. The cover of claim 1, wherein the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof.

6. The cover of claim 1, wherein the hydrophobic coating has a thickness of from about 10 nm to about 100 nm.

7. The cover of claim 1, wherein the paint layer comprises:
a primer layer;
a base coat layer; and
a top coat layer.

8. The cover of claim 7, wherein the primer layer comprises polyurethane, epoxy, epoxy-polyester, polyester, and combinations thereof.

9. The cover of claim 7, wherein the base coat layer comprises:
polyurethane, polyacrylic, polyester, and combinations thereof; and
pigments,
wherein the pigments are selected from the group consisting of carbon black, titanium dioxide, clay, mica, talc, barium sulfate, calcium carbonate, aluminum oxide, plastic beads, color pigments, dyes, and combinations thereof.

10. The cover of claim 7, wherein the top coat layer comprises polyacrylics, polyurethanes, urethane acrylates, acrylic acrylates, epoxy acrylates, and combinations thereof.

11. An electronic device comprising:
an electronic component; and
a cover enclosing the electronic component, the cover comprising:
a substrate comprising a first metal;
a second metal injection molded on the surface of the substrate;
a paint layer or an electrophoretic deposition layer on the second metal surface;
a chamfered edge on the substrate, wherein the chamfered edge cuts through the paint layer or the electrophoretic deposition layer, the second metal, and partially through the first metal; and
a hydrophobic coating.

12. The electronic device of claim 11, wherein the electronic device is a laptop, a desktop computer, a keyboard, a mouse, a smartphone, a tablet, monitor, a television screen, a speaker, a game console, a video player, an audio player, or a combination thereof.

13. The electronic device of claim 11, wherein:
the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluorotelomers, polytetrafluoroethylene, polyvinylidenefluouride, fluorosiloxane, fluoro UV polymers, and combinations thereof; and
the hydrophobic coating has a thickness of from about 10 nm to about 100 nm.

14. A method of making a cover for an electronic device comprising:
depositing a first metal on a substrate;
injection molding a second metal on the surface of the substrate;
applying a paint layer or an electrophoretic deposition layer on the second metal surface;
chamfering an edge on the substrate, wherein the chamfered edge cuts through the paint layer or the electrophoretic deposition layer, the second metal, and partially through the first metal; and
then applying a hydrophobic coating.

15. The method of claim 14, wherein:
the hydrophobic coating is selected from the group consisting of silanes, fluorinated olefin-based polymers, specialty fluoroacrylates, fluorosilicone acrylates, fluorourethanes, perfluoropolyethers, perfluoropolyoxetanes, fluoratelomers, polytetrafluoroethylene, polyvinylidenefluouride, fluorosiloxane, fluoro UV polymers, and combinations thereof; and
the hydrophobic coating has a thickness of from about 10 nm to about 100 nm.
